(19) United States
(12) Patent Application Publication
(10) Pub. No.: US 2014/0015099 A1
(43) Pub. Date: Jan. 16, 2014

(54) SEMICONDUCTOR DEVICE AND METHOD FOR FABRICATING THE SAME

(71) Applicant: SK HYNIX INC., Icheon (KR)

(72) Inventor: Ju Hee HWANG, Seoul (KR)

(73) Assignee: SK HYNIX INC., Icheon (KR)

(21) Appl. No.: 13/716,057

(22) Filed: Dec. 14, 2012

(30) Foreign Application Priority Data
Jul. 16, 2012 (KR) 10-2012-0077256

(51) Int. Cl. H01L 49/02

(52) U.S. Cl. CPC H01L 28/40
USPC 257/532; 438/386

(57) ABSTRACT

A semiconductor device and a method for fabricating the same are disclosed, which can form a nitride floating capacitor (NFC) serving as a support structure in the form of a multi-layer structure, thereby preventing a storage node from leaning. The semiconductor device includes a plurality of storage nodes formed over a semiconductor substrate; and a multi-layered support pattern formed between the plurality of storage nodes, wherein individual support patterns included in the multi-layered support layer pattern are different in shapes or directions in which the individual support patterns are arranged from each other.

### CROSS-REFERENCE TO RELATED APPLICATION

The present application claims priority to Korean patent application No. 10-2012-0077256 filed on 16 Jul. 2012, which is incorporated by reference in its entirety.

### BACKGROUND OF THE INVENTION

Embodiments of the present invention relate to a semiconductor device and a method for fabricating the same, and more particularly to a technology for forming a nitride floating capacitor (NFC).

In a semiconductor device, a capacitor needs to be refreshed. Although there is a need to maximize capacitance to achieve a longer refresh time, there is a limitation in maximizing capacitance due to higher integration and miniaturization of memory devices. Accordingly, in order to guarantee capacitance, the height of a capacitor can be increased and the thickness of a capacitor dielectric film can be reduced, because capacitance is proportional both to an area of an electrode and to a dielectric constant (i.e., permittivity) of a dielectric film, and is inversely proportional to the thickness of the dielectric-film provided in a space between electrodes. However, it is difficult to find a dielectric material having a high dielectric constant (or high permittivity). Therefore, in order to implement a highly-integrated semiconductor device, a method for increasing the surface area by increasing the height of a capacitor has been widely used.

Generally, a cylinder-type capacitor having a high aspect ratio has been widely used to increase the surface area of an electrode. In the cylinder-type capacitor, both an inner surface and an outer surface of a lower electrode of the capacitor can be used as an effective surface area of the capacitor, resulting in a higher capacitance. In order to form the cylinder-type capacitor, a wet dip-out process for removing an insulation film formed between lower electrodes of the capacitor is essential. However, when the insulation film formed between the lower electrodes of the capacitor using the wet dip-out process is removed, leaning or collapse of the lower electrode of the capacitor occurs. Specifically, if the capacitor has a high aspect ratio due to the highly-integrated semiconductor device, leaning of the lower electrode of the capacitor becomes serious.

In order to overcome the above-mentioned problems, a nitride floating capacitor (NFC) structure has recently been widespread, which can prevent leaning of a lower electrode of each capacitor by binding lower electrodes of a plurality of capacitors with a support layer formed of a nitride film.

However, with the development of technology capable of more highly integrating the cell structure, it is more difficult to guarantee a cell space while the height of a storage node is gradually increased. As a result, even if the NFC structure is used, a storage node unavoidably leans.

### BRIEF SUMMARY OF THE INVENTION

Various embodiments of the present invention are directed to providing a semiconductor device and a method for fabricating the same that substantially obviate one or more problems due to limitations and disadvantages of the related art.

An embodiment of the present invention relates to a semiconductor device including a multi-layer NFC structure in which NFCs arranged to cross each other are coupled to different storage nodes so that a storage node is prevented from leaning, and a method for fabricating the same.

In accordance with an aspect of the present invention, a semiconductor device includes: a plurality of storage nodes formed over a semiconductor substrate; and a multi-layered support pattern formed between the plurality of storage nodes, wherein individual support patterns included in the multi-layered support layer pattern are different in shapes or directions in which the individual support patterns are arranged from each other.

The multi-layered support pattern includes: a first support pattern in a first shape; and a second support pattern formed over the first support pattern in the same shape as the first shape and arranged perpendicular to the first support pattern.

The multi-layered support pattern includes: a first support pattern in a first shape; and a second support pattern formed over the first support pattern in a different shape from the first shape.

An individual support pattern included in the multi-layered support pattern is any of a line-shaped pattern, a diagonal pattern, a negative elliptical pattern, a negative hole-shaped pattern, and a wave-shaped pattern.

The multi-layered support pattern includes: a first support pattern coupled to a first storage node and a second storage node; and a second support pattern located at a different level from the first support pattern, and coupled to the second storage node and a third storage node.

In accordance with an aspect of the present invention, a method for fabricating a semiconductor device includes: forming a first insulation film over a semiconductor substrate; forming a first support pattern over the first insulation film or at an inner portion of the first insulation film; forming a second insulation film over the first support pattern and the first insulation film; forming a first support pattern over the first insulation film or at an inner portion of the first insulation film in such a manner that the second support pattern is formed in a different direction or in different shape from the first support pattern; forming a third insulation film over the second support pattern and the second insulation film; and forming a storage node by etching the first support pattern, the second insulation film, the second support pattern, and the third insulation film.

The forming the first support pattern, a nitride material is deposited over the first insulation film and the nitride material is patterned to form the first support pattern.

The forming the second support pattern, a nitride material is deposited over the second insulation film and the nitride material is patterned to form the second support pattern.

The forming of the first support pattern includes: forming a first trench by etching the first insulation film; and filling the first trench with a dielectric material and planarizing the dielectric material to form the first support pattern in the first trench.

The forming of the second support pattern includes: forming a second trench in the second insulation film; and filling the second trench with a dielectric material and planarizing the dielectric material to form the second support pattern.

Each of the first support pattern and the second support pattern is formed in any of a line shape, a diagonal shape, a negative elliptical shape, a negative hole shape, and a wave shape.

The formation of the second support pattern, the second support pattern is formed perpendicular to the first support pattern.

The forming of the storage node includes: forming a trench by etching the first support pattern, the first insulation film, the second support pattern, and the third insulation film; forming a conductive film along an inner surface of the trench; removing the first insulation film, the second insulation film, and the third insulation film using a dip-out process; and forming a dielectric film and an upper electrode over a surface of the conductive film.

In accordance with another aspect of the present invention, a method for fabricating a semiconductor device includes: forming a first insulation film over a semiconductor substrate; forming a first support pattern over the first insulation film or at an inner portion of the first insulation film; forming a second insulation film over the first support pattern and the first insulation film; forming a third insulation film over the second insulation film; forming a second support pattern over the first insulation film or at an inner portion of the third insulation film in such a manner that the second support pattern is formed in a different direction or in a different shape from the first support pattern; forming a fourth insulation film over the second support pattern and the third insulation film; and forming a storage node by etching the first support pattern, the third insulation film, the second support pattern, and the fourth insulation film.

The first insulation film includes Phosphorous Silicate Glass (PSG), and the second insulation film includes Tetra Ethyl Ortho Silicate (TEOS).

In accordance with another aspect of the present invention, a method for fabricating a semiconductor device includes: forming a multi-layered support pattern interconnecting a plurality of storage nodes and formed over a semiconductor substrate, wherein individual support patterns of the multi-layered support pattern at different levels from each other are coupled to different storage nodes; and forming a plurality of storage nodes coupled to different support patterns of the multi-layered support pattern.

The forming of the multi-layered support pattern includes: forming individual support patterns of the multi-layered support pattern in different shapes or extending in different directions from each other.

The forming of the multi-layered support pattern includes: forming a first support pattern in a line shape or a negative elliptical shape; and

forming a second support pattern in a line shape or a negative elliptical shape over the first support pattern in such a manner that the second support pattern is formed perpendicular to the first support pattern.

The forming of the multi-layered support pattern includes: forming a first support pattern in a negative elliptical shape; and forming a second support pattern in a line shape over the first support pattern.

The forming of the multi-layered support pattern includes: forming a first support pattern configured to interconnect a first storage node and a second storage node; and forming a second support pattern at a different level from the first support pattern in such a manner that the second support pattern is coupled to the second storage node and a third storage node.

A semiconductor device includes a first support pattern formed at a first level and coupling a first group of storage nodes to each other; and a second support pattern formed at a second level different from the first level and coupling a second group of storage nodes to each other.

The first and the second groups of storage nodes share at least one storage node in common.

The first group of storage nodes includes first and second storage nodes, and wherein the second group of storage nodes includes the second storage node and a third storage node.

The first and the second support pattern are each any of a line-shaped pattern, a diagonal pattern, a negative elliptical pattern, a negative hole-shaped pattern, and a wave-shaped pattern.

The first support pattern is a line pattern extending in a first direction, and wherein the second support pattern is a line pattern extending in a second direction different from the first direction.

The first support pattern is a negative elliptical pattern and couples a plurality of storage nodes to each other, and wherein the second support pattern is a line pattern and couples a part of the plurality of storage nodes to each other.

A method for fabricating a semiconductor device includes forming a first insulation film over a semiconductor substrate; forming a first trench by etching the first insulation film; filling the first trench with a dielectric material and planarizing the dielectric material to form the first support pattern in the first trench; forming a second insulation film over the first support pattern and the first insulation film; forming a second trench in the second insulation film in a different direction or in different shape from the first support pattern; filling the second trench with a dielectric material and planarizing the dielectric material to form the second support pattern; forming a third insulation film over the second support pattern and the second insulation film; and forming a storage node by etching the first support pattern, the second insulation film, the second support pattern, and the third insulation film.

It is to be understood that both the foregoing general description and the following detailed description of the present invention are exemplary and explanatory and are intended to provide further explanation of the invention as claimed.

### BRIEF DESCRIPTION OF THE DRAWINGS

FIG. 1 is a conceptual diagram illustrating a multi-layer nitride floating capacitor (NFC) according to an embodiment of the present invention.

FIG. 2 is a plan view illustrating a semiconductor device according to a first embodiment of the present invention.

FIG. 3A is a plan view illustrating a first level of the multiple-layer NFC in the semiconductor device shown in FIG. 2.

FIG. 3B is a plan view illustrating a second level of the multiple-layer NFC in the semiconductor device shown in FIG. 2.

FIGS. 4A to 4J are cross-sectional views illustrating a method for forming a semiconductor device according to a first embodiment of the present invention.

FIG. 5 is a plan view illustrating a semiconductor device according to a second embodiment of the present invention.

FIG. 6A is a plan view illustrating a first level of the multiple-layer NFC of the semiconductor device shown in FIG. 5.

FIG. 6B is a plan view illustrating a second level of the multiple layers of the semiconductor device shown in FIG. 5.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts. In the following description of the present invention, a detailed description of related known configurations or functions incorporated herein will be omitted when it may make the subject matter of the present invention unclear.

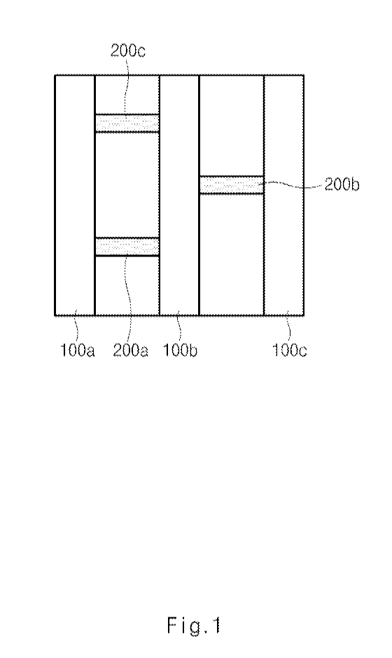

A semiconductor device and a method for fabricating the same according to embodiments of the present invention will hereinafter be described with reference to FIGS. 1 to 6B.

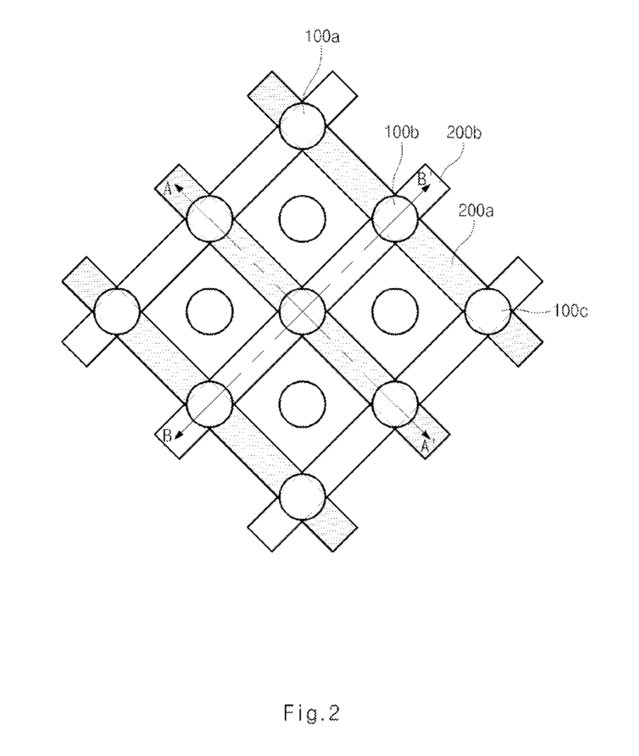

FIG. 1 is a conceptual diagram illustrating a multi-layer NFC according to an embodiment of the present invention and FIG. 2 is a plan view illustrating a semiconductor device according to a first embodiment of the present invention.

Referring to FIG. 1, NFCs (200a˜200c) (also referred to as a support pattern) located among storage nodes (100a˜100c) have a multi-layer structure. Referring to FIG. 2, in an embodiment, the multi-layer NFCs (200a˜200c) are formed perpendicular to each other. Although the present invention exemplarily discloses NFCs (200a˜200c) arranged perpendicular to each other for convenience of description, the NFCs (200a˜200c) may also be arranged to cross each other in an acute or obtuse angle.

Referring again to FIG. 1, a first NFC 200a located between storage nodes (100a, 100b) is formed at a first level, a second NFC 200b arranged between storage nodes (100b, 100c) is formed at a second level different from the first level, and a third NFC 200c located between the storage nodes (100a, 100b) is formed at a third level different from the first and the second levels. As a result, one or more NFCs may be formed among the storage nodes (100a˜100c), and individual NFCs are formed at different levels.

As described above, an embodiment of the present invention forms a multi-layer NFC structure so that different storage nodes are interconnected with each other. As a result, the storage nodes may be tightly fixed in place, thereby preventing the storage nodes secured by any NFC from leaning.

FIG. 2 is a plan view illustrating a semiconductor device according to a first embodiment of the present invention.

Referring to FIG. 2, a first NFC 200a shaped as a line is formed between the storage nodes 100a˜100c. A second NFC 200b shaped as a line is formed perpendicular to the first NFC 200a at a different level from the first NFC 200a.

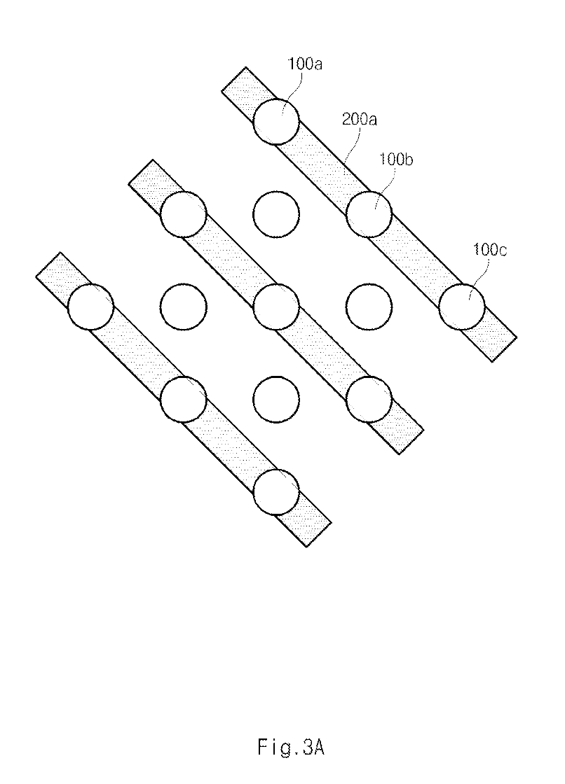

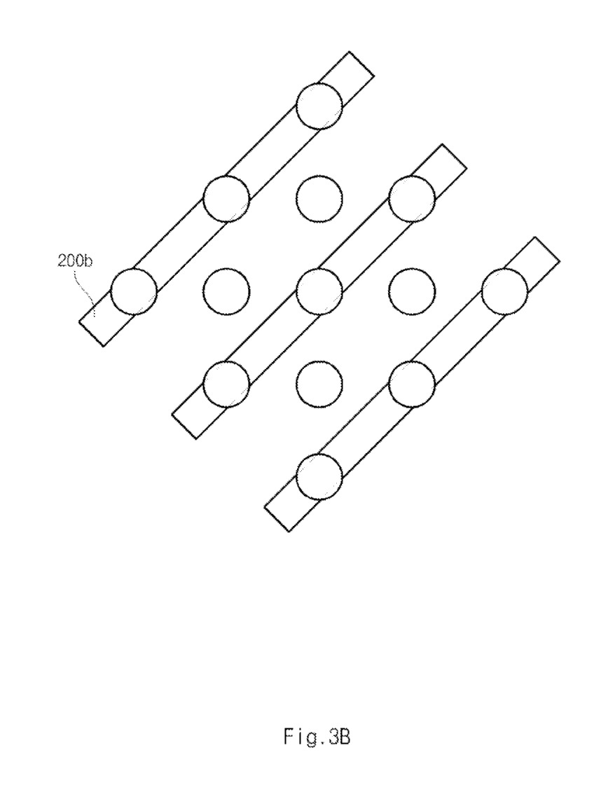

FIGS. 3A and 3B are exploded plan views illustrating the multi-layer NFC shown in FIG. 2. In more detail, FIG. 3A is a plan view of a first level where the first NFC 200a of the semiconductor device shown in FIG. 2 is formed. FIG. 3B is a plan view of a second level where the second NFC 200b of the semiconductor device shown in FIG. 2 is formed.

As described above, an NFC is comprised of multiple layers extending in different directions at different levels from each other so as to prevent a tall capacitor from falling down or leaning to a side.

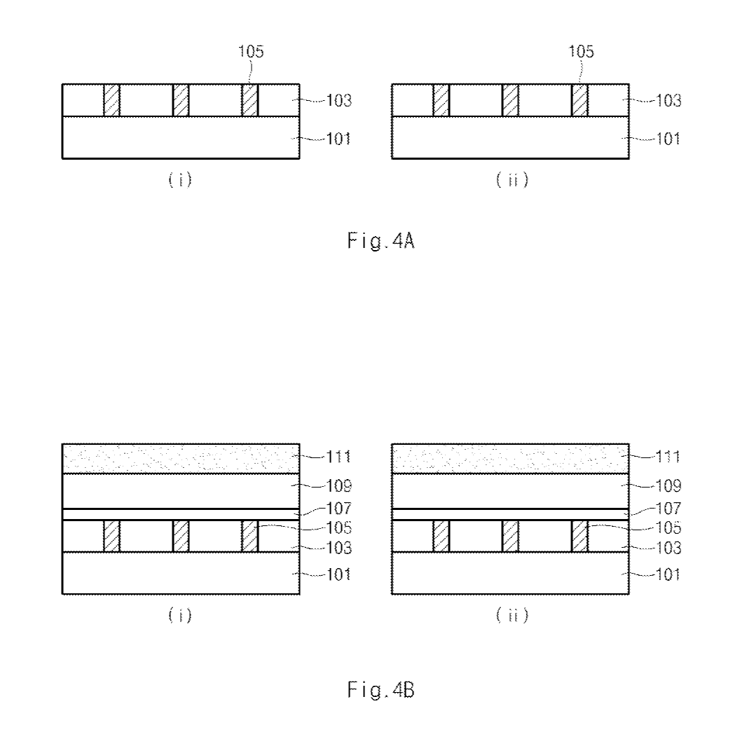

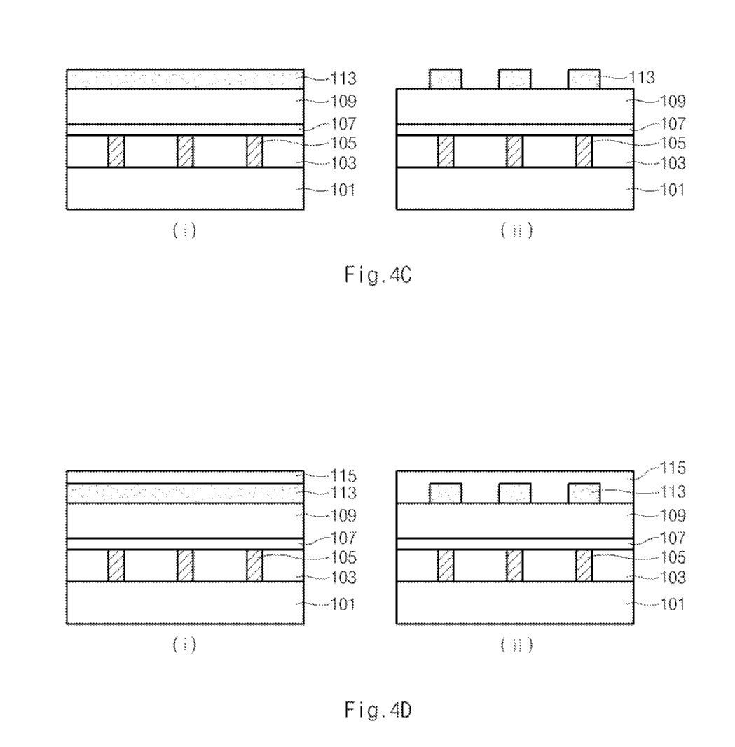

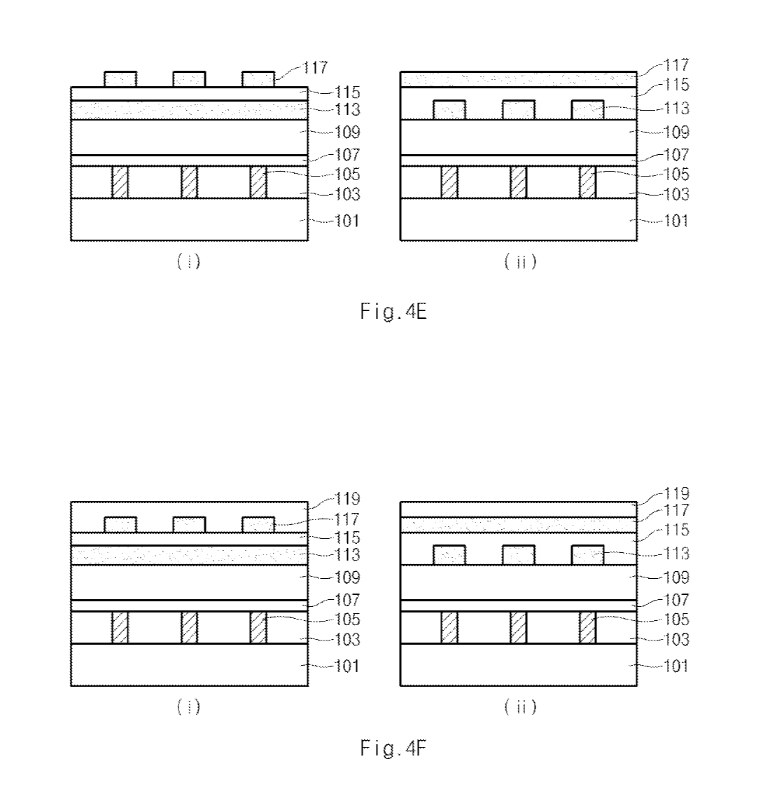

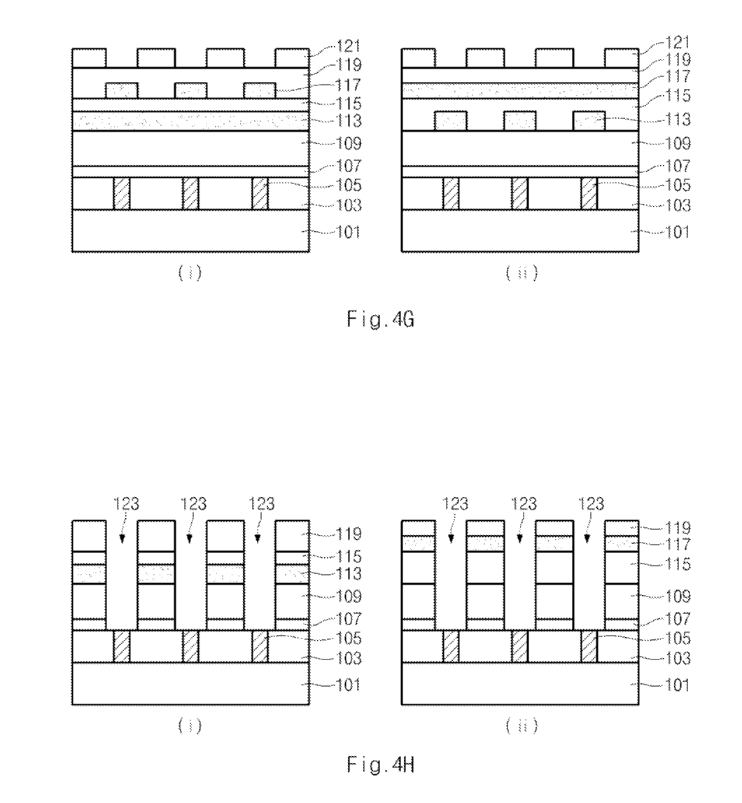

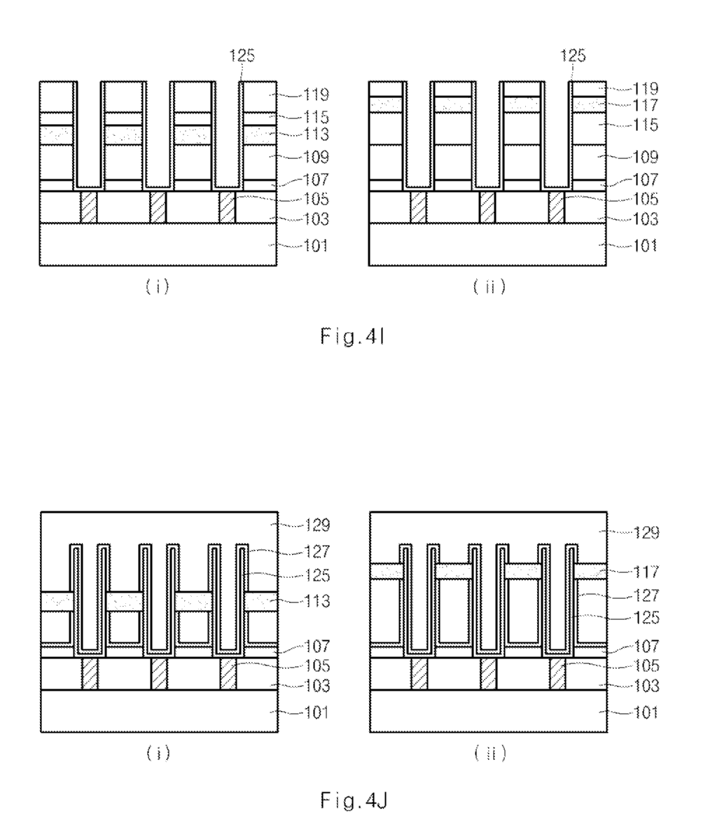

FIGS. 4A to 4J are cross-sectional views illustrating a method for forming a semiconductor device according to a first embodiment of the present invention. The method for forming the semiconductor device according to the first embodiment of the present invention will hereinafter be described with reference to FIGS. 4A to 4J. In FIGS. 4A to 4J, (i) is a cross-sectional view illustrating the semiconductor device taken along the line A-A′ of FIG. 2, and (ii) is a cross-sectional view illustrating the semiconductor device taken along the line B-B′ of FIG. 2.

Referring to FIG. 4A, an interlayer insulation film 103 is formed over a semiconductor substrate 101, and a photoresist pattern (not shown) defining a storage node contact region is formed over the interlayer insulation film 103. Subsequently, the interlayer insulation film 103 is etched using the photoresist pattern as an etch mask so as to form a contact hole (not shown). A conductive material (for example, a polysilicon material) is formed to fill the contact hole and then planarized, so that a storage node contact plug (SNCP) 105 is formed. In an embodiment, the planarization may be achieved by a chemical mechanical polishing (CMP) or etch-back process.

Referring to FIG. 4B, an etch stop layer 107 is formed over the entire surface on which the storage node contact plug (SNCP) 105 is formed, and an isolation insulation layer 109 is formed over the etch stop layer 107. In an embodiment, the etch stop layer 107 may be formed of a nitride material. The isolation insulation layer 109 may be formed by sequentially depositing a Phosphorous Silicate Glass (PSG) and a Tetra Ethyl Ortho Silicate (TEOS), or may also be formed of any one of oxide films, for example, Boro-phospho Silicate Glass (BPSG), Phosphorous Silicate Glass (PSG), Tetra Ethyl Ortho Silicate (TEOS), Undoped Silicate Glass (USG), High Density Plasma (HDP), and a combination thereof. In addition, the isolation insulation film 109 is deposited to a predetermined thickness through which the oxide film can guarantee the size of an area required for desired dielectric capacitance.

Subsequently, an NFC material 111 is deposited over the isolation insulation layer 109. The NFC material 111 is formed of a nitride material, and includes a silicon nitride film or a silicon oxynitride (SiON) film.

Referring to FIG. 4C, the NFC material 111 formed by the process of FIG. 4B is etched and patterned to a predetermined thickness, so that a first NFC 113 is formed. FIG. 4C(i) shows the patterned NFC 113 shaped in a line, and FIG. 4C(ii) shows the patterned NFC 113 shaped in an island.

Referring to FIG. 4D, an insulation film 115 is formed over the entire top surface of the first NFC 113. In an embodiment, the insulation film 115 prevents the first NFC 113 from being damaged in a subsequent process, and may be formed of any one of oxide films, such as a BPSG, a PSG, a TEOS, a USG, a HDP, and a combination thereof.

Referring to FIG. 4E, an NFC material is deposited over the insulation film 115, and patterned to form a second NFC 117 perpendicular to the first NFC 113. In an embodiment, the NFC material contained in the second NFC 117 may be formed of the same material as the first NFC 113. The first NFC 113 and the second NFC 117 may be formed in the form of a multi-layer structure, and may also be arranged perpendicular to each other. The first and second NFCs 113 and 117 can prevent the storage node from leaning in a subsequent wet dip-out process.

Referring to FIG. 4F, an insulation film 119 is deposited over the second NFC 117. The insulation film 119 may prevent the second NFC 117 from being damaged in a subsequent process. The insulation film 119 may be formed of any one of oxide films, for example, BPSG, PSG, TEOS, USG, HDP, and a combination thereof.

Referring to FIG. 4G, a photoresist pattern 121 for forming an open region to define a storage node is formed over the insulation film 119.

Referring to FIG. 4H, the insulation film 119, the second NFC 117, the insulation film 115, the first NFC 113, and the isolation insulation layer 109 are sequentially etched using the photoresist pattern 121 as a mask. The etch stop layer 107 is then etched, so that the open region 123 exposing the storage node contact plug (SNCP) 105 is formed. Although not shown in the drawings, in an embodiment, a size of a lower region of the open region 123 can be enlarged using a wet etching process on the oxide film in a subsequent process. That is, if the isolation insulation layer 109 is formed by sequentially depositing PSG and TEOS, a lower PSG is more rapidly etched than an upper TEOS, so that a size of a lower part of the open region 123 becomes increased by a subsequent wet etching process.

Referring to FIG. 4I, a conductive film 125 to be used as a storage node is deposited over the entire surface on which the open region 123 is formed. Then, a storage-node isolation process is carried out in such a manner that a storage node is formed in the open region 123. In an embodiment, the storage node may be a cylindrical storage node.

Referring to FIG. 4J, the isolation insulation layer 109 and the insulation films 119 and 115 are completely removed by a wet dip-out process. In an embodiment, the wet dip-out process may be carried out using a wet chemical material such as a hydrogen fluoride (HF) or a buffered oxide etchant (BOE) solution.

Thereafter, a dielectric film 127 and an upper electrode 129 are sequentially formed over the conductive film 125, resulting in a capacitor.

Although FIGS. 4A to 4J illustrate a two-layered NFC structure, the processes shown in FIGS. 4B to 4F can be repeatedly carried out so that the NFC may also be a three-layered configuration or more.

In an exemplary embodiment of the present invention, a stack of PSG and TEOS is employed for the isolation insulation layer 109. Then, the NFC 113 is formed over the isolation insulation layer 109. However, the isolation insulation layer 109 can be formed of PSG. Then, the NFC material is deposited over the PSG to form an NFC pattern, and TEOS as the insulation film 115 may be formed over the NFC pattern.

Although the embodiment forms the NFC using an etching process, it should be noted that the NFC patterning process may also be carried out using a damascene process.

A detailed description of a damascene process is as follows. In accordance with a damascene process, an insulation film (also called a dielectric layer) is patterned by a photolithography process so as to form a trench, the trench is filled with a conductive material such as tungsten (W), aluminum (Al), or copper (Cu), and the remaining conductive materials are removed using an etch-back process or a CMP process.

In other words, as shown in FIGS. 4B and 4D, after the isolation insulation layer 109 and the insulation film 115 are formed, a trench is formed in the isolation insulation layer 109 and the insulation film 115. An NFC material is buried in the trench and then planarized, and the resultant NFCs 113 and 117 can be patterned using a mask (not shown).

As described above, NFCs 113 and 117 between the storage nodes form a multi-layer structure that interconnects different storage nodes, so that collapse of the storage nodes can be prevented and a height of a capacitor can be increased. As a result, a more elongated capacitor can occupy a smaller area in a given cell region.

In addition, although the NFCs 113 and 117 can be formed in a double-leveled structure arranged in the same direction, the NFCs 113 and 117 can also be formed in a double-leveled structure arranged in different directions to provide additional support and prevent leaning of the storage nodes.

In addition, since the method for fabricating the semiconductor device according to an embodiment of the present invention performs NFC patterning before the storage node is formed, the present invention can provide various advantages. For example some of the problems overcome by patterning the NFC before forming the storage node include: (i) difficulties in etching an NFC formed at a lower level in a subsequent NFC pattering process and (ii) unexpected damage to a storage node serving as a capacitor occurring while the NFC is patterned.

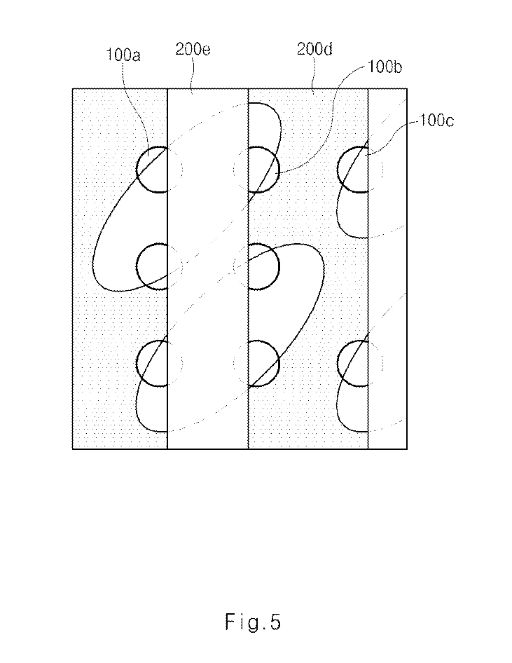

FIG. 5 is a plan view illustrating a semiconductor device according to a second embodiment of the present invention.

Referring to FIG. 5, negative elliptical NFC 200d is formed between the storage nodes 100 at a first level. That is, the material that forms the NFC 200d may have an elliptical-shaped hole. A line-shaped NFC 200e is formed at a second level.

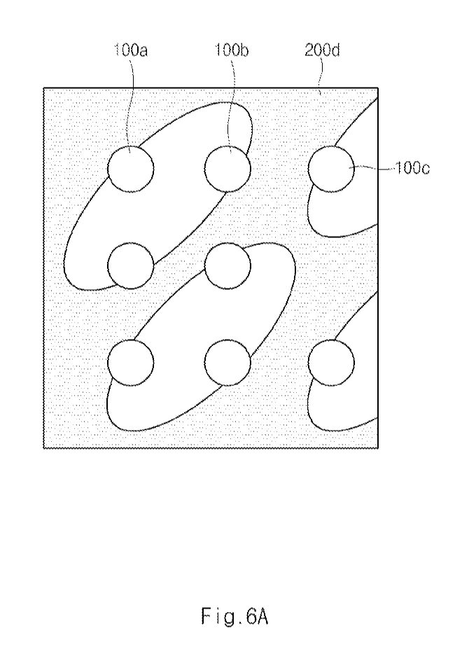

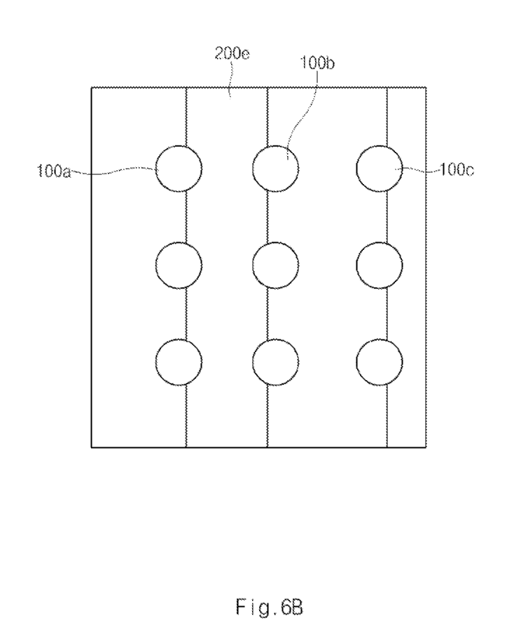

FIGS. 6A and 6B are exploded plan views illustrating the multi-layer NFC shown in FIG. 5. FIG. 6A is a plan view illustrating a structure of a multiple-level NFC shown in FIG. 5 at the first level. FIG. 6B is a plan view illustrating a structure of the multiple-level NFC shown in FIG. 5 at a second level.

As described above, the present invention forms various types of NFCs at different levels. For example, a line-shaped NFC, a diagonal NFC, a negative elliptical NFC, a negative hole-shaped NFC, a wave-shaped NFC, etc., can be employed. The NFC can combine multiple storage nodes into one bundle as the negative NFC 200d shown in FIG. 5 does at the first level. As a result, compared to the conventional art using a single NFC provided at a single level, the present invention can more effectively prevent the storage nodes from falling down or leaning to a side. Thus, a capacitor can be formed taller and a cell area available for other elements can be increased. In addition, in a semiconductor device according to an embodiment of the present invention, three or more storage nodes are coupled to each other, so that the dip-out process can be easily achieved without a concern that the storage nodes would fall down.

As is apparent from the above description, a semiconductor device and a method for fabricating the same according to embodiments of the present invention have the following characteristics.

First, a multi-layer NFC structure, in which several NFCs are coupled to storage nodes at different levels, is formed to prevent the storage node from falling down, such that the height of a capacitor can be increased, resulting in an increase in a cell area available for other elements.

Second, different NFCs in a multi-layer NFC pattern formed according to the present invention may have different configurations. NFC patterns may be formed in different shapes or in different directions at different levels, so that the resultant NFC patterns can further enhance the stability of the storage node falling down.

Third, the NFC pattern is formed before the storage node is formed, so that a lower NFC can be easily etched.

Those skilled in the art will appreciate that the present invention may be carried out in other specific ways than those set forth herein without departing from the spirit and essential characteristics of the present invention. The above exemplary embodiments are therefore to be construed in all aspects as illustrative and not restrictive. The scope of the invention should be determined by the appended claims and their legal equivalents, not by the above description, and all changes coming within the meaning and equivalency range of the appended claims are intended to be embraced therein. Also, it is obvious to those skilled in the art that claims that are not explicitly cited in each other in the appended claims may be presented in combination as an exemplary embodiment of the present invention or included as a new claim by a subsequent amendment after the application is filed.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a plurality of storage nodes formed over a semiconductor substrate; and
a multi-layered support pattern formed between the plurality of storage nodes,
wherein individual support patterns included in the multi-layered support layer pattern are different in shapes or directions in which the individual support patterns are arranged from each other.

2. The semiconductor device according to claim 1, wherein the multi-layered support pattern includes:
a first support pattern in a first shape; and
a second support pattern formed over the first support pattern in the same shape as the first shape and arranged perpendicular to the first support pattern.

3. The semiconductor device according to claim 1, wherein the multi-layered support pattern includes:
a first support pattern in a first shape; and
a second support pattern formed over the first support pattern in a different shape from the first shape.

4. The semiconductor device according to claim 1, wherein an individual support pattern included in the multi-layered support pattern is any of a line-shaped pattern, a diagonal pattern, a negative elliptical pattern, a negative hole-shaped pattern, and a wave-shaped pattern.

5. The semiconductor device according to claim 1, wherein the multi-layered support pattern includes:
a first support pattern coupled to a first storage node and a second storage node; and
a second support pattern located at a different level from the first support pattern, and coupled to the second storage node and a third storage node.

6. A method for fabricating a semiconductor device comprising:
forming a first insulation film over a semiconductor substrate;
forming a first support pattern over the first insulation film or at an inner portion of the first insulation film;
forming a second insulation film over the first support pattern and the first insulation film;
forming a second support pattern over the first insulation film or at an inner portion of the second insulation film in such a manner that the second support pattern is formed in a different direction or in different shape from the first support pattern;
forming a third insulation film over the second support pattern and the second insulation film; and
forming a storage node by etching the first support pattern, the second insulation film, the second support pattern, and the third insulation film.

7. The method according to claim 6, wherein, in forming the first support pattern, a nitride material is deposited over the first insulation film and the nitride material is patterned to form the first support pattern.

8. The method according to claim 6, wherein, in forming the second support pattern, a nitride material is deposited over the second insulation film and the nitride material is patterned to form the second support pattern.

9. The method according to claim 6, wherein the forming of the first support pattern includes:
forming a first trench by etching the first insulation film; and
filling the first trench with a dielectric material and planarizing the dielectric material to form the first support pattern in the first trench.

10. The method according to claim 6, wherein the forming of the second support pattern includes:
forming a second trench in the second insulation film; and
filling the second trench with a dielectric material and planarizing the dielectric material to form the second support pattern.

11. The method according to claim 6, wherein each of the first support pattern and the second support pattern is formed in any of a line shape, a diagonal shape, a negative elliptical shape, a negative hole shape, and a wave shape.

12. The method according to claim 6, wherein:
in the formation of the second support pattern, the second support pattern is formed perpendicular to the first support pattern.

13. The method according to claim 6, wherein the forming of the storage node includes:
forming a trench by etching the first support pattern, the first insulation film, the second support pattern, and the third insulation film;
forming a conductive film along an inner surface of the trench;
removing the first insulation film, the second insulation film, and the third insulation film using a dip-out process; and
forming a dielectric film and an upper electrode over a surface of the conductive film.

14. A method for fabricating a semiconductor device comprising:
forming a first insulation film over a semiconductor substrate;
forming a first support pattern over the first insulation film or at an inner portion of the first insulation film;
forming a second insulation film over the first support pattern and the first insulation film;
forming a third insulation film over the second insulation film;
forming a second support pattern over the first insulation film or at an inner portion of the third insulation film in such a manner that the second support pattern is formed in a different direction or in a different shape from the first support pattern;
forming a fourth insulation film over the second support pattern and the third insulation film; and
forming a storage node by etching the first support pattern, the third insulation film, the second support pattern, and the fourth insulation film.

15. The method according to claim 14, wherein the first insulation film includes Phosphorous Silicate Glass (PSG), and the second insulation film includes Tetra Ethyl Ortho Silicate (TEOS).

16. A method for fabricating a semiconductor device comprising:
forming a multi-layered support pattern interconnecting a plurality of storage nodes and formed over a semiconductor substrate,
wherein individual support patterns of the multi-layered support pattern at different levels from each other are coupled to different storage nodes; and
forming a plurality of storage nodes coupled to different support patterns of the multi-layered support pattern.

17. The method according to claim 16, wherein the forming of the multi-layered support pattern includes:
forming individual support patterns of the multi-layered support pattern in different shapes or extending in different directions from each other.

18. The method according to claim 16, wherein the forming of the multi-layered support pattern includes:
forming a first support pattern in a line shape or a negative elliptical shape; and
forming a second support pattern in a line shape or a negative elliptical shape over the first support pattern in such a manner that the second support pattern is formed perpendicular to the first support pattern.

19. The method according to claim 16, wherein the forming of the multi-layered support pattern includes:
forming a first support pattern in a negative elliptical shape; and
forming a second support pattern in a line shape over the first support pattern.

20. The method according to claim 16, wherein the forming of the multi-layered support pattern includes:
forming a first support pattern configured to interconnect a first storage node and a second storage node; and
forming a second support pattern at a different level from the first support pattern in such a manner that the second support pattern is coupled to the second storage node and a third storage node.

21. A semiconductor device comprising:
a first support pattern formed at a first level and coupling a first group of storage nodes to each other; and
a second support pattern formed at a second level different from the first level and coupling a second group of storage nodes to each other.

22. The semiconductor device of claim 21,
wherein the first and the second groups of storage nodes share at least one storage node in common.

23. The semiconductor device of claim 21,
wherein the first group of storage nodes includes first and second storage nodes, and
wherein the second group of storage nodes includes the second storage node and a third storage node.

24. The semiconductor device of claim 21,
wherein the first and the second support pattern are each any of a line-shaped pattern, a diagonal pattern, a negative elliptical pattern, a negative hole-shaped pattern, and a wave-shaped pattern.

25. The semiconductor device of claim 23,
wherein the first support pattern is a line pattern extending in a first direction, and
wherein the second support pattern is a line pattern extending in a second direction different from the first direction.

26. The semiconductor device of claim 23,
wherein the first support pattern is a negative elliptical pattern and couples a plurality of storage nodes to each other, and
wherein the second support pattern is a line pattern and couples a part of the plurality of storage nodes to each other.

27. A method for fabricating a semiconductor device comprising:
forming a first insulation film over a semiconductor substrate;
forming a first trench by etching the first insulation film;
filling the first trench with a dielectric material and planarizing the dielectric material to form the first support pattern in the first trench;
forming a second insulation film over the first support pattern and the first insulation film;
forming a second trench in the second insulation film in a different direction or in different shape from the first support pattern;
filling the second trench with a dielectric material and planarizing the dielectric material to form the second support pattern;
forming a third insulation film over the second support pattern and the second insulation film; and
forming a storage node by etching the first support pattern, the second insulation film, the second support pattern, and the third insulation film.
